(19) United States
(12) Patent Application Publication
(10) Pub. No.: US 2026/0128746 A1
(43) Pub. Date: May 7, 2026

(54) FREQUENCY SYNTHESIZER

(71) Applicant: University of Twente, Enschede (NL)

(72) Inventors: Maryam Dodangeh, 's- Hertogenbosch (NL); Mark Stefan Oude Alink, Enschede (NL); Bram Nauta, Enschede (NL)

(73) Assignee: University of Twente, Enschede (NL)

(21) Appl. No.: 19/436,421

(22) Filed: Dec. 30, 2025

(51) Int. Cl. H03L 7/099; H03K 3/03

(52) U.S. Cl. CPC H03L 7/0995; H03K 3/0315

(57) ABSTRACT

A frequency synthesizer includes a ring oscillator coupled to a multiplexer and a controller. The ring oscillator has a plurality of stages so that each stage provides a corresponding square wave signal. The multiplexer has a plurality of input channels and one or more outputs for providing an output signal at a predetermined output frequency. Each input channel is coupled to a corresponding stage of the ring oscillator. The controller generates one control signal per output. Each control signal is configured to select an input channel among the plurality of input channels according to a predetermined sequence to obtain the output signal at the predetermined output frequency.

### TECHNICAL FIELD

The present disclosure relates to a frequency synthesizer, and in particular to a non-integer frequency synthesizer.

### BACKGROUND

Non-integer frequency synthesizers, often referred to as fractional-N phase-locked loops (PLLs), are electronic circuits capable of generating output frequencies that are not simple integer multiples of a reference frequency. This flexibility is achieved by finely controlling the ratio between the reference and output frequencies, allowing for precise frequency generation over a wide range. Such synthesizers are essential in modern wireless communication systems, where the ability to rapidly and accurately switch between frequencies is crucial.

In Bluetooth Low Energy (BLE) chips, non-integer frequency synthesizers are used to generate the various carrier frequencies required for communication. BLE protocols demand frequent frequency hopping to minimise interference and comply with regulatory standards. The synthesizer's ability to quickly move between channels ensures reliable connectivity and efficient spectrum use, making it a fundamental component in BLE transceivers.

However, traditional non-integer frequency synthesizers can suffer from relatively high-power consumption and long settling times, which are especially problematic in battery-powered BLE devices. Improving these aspects is essential because lower power consumption extends device battery life, and faster settling times enable quicker channel changes, reducing latency and improving overall performance. As BLE devices become more prevalent in wearables and IoT applications, the demand for synthesizers that combine high performance with energy efficiency continues to grow.

It is an object of the disclosure to address one or more of the above-mentioned limitations.

### SUMMARY

According to a first aspect of the disclosure, there is provided a frequency synthesizer comprising:
a ring oscillator comprising a plurality of stages, wherein each stage is configured to provide a corresponding square wave signal;
a multiplexer having a plurality of input channels and one or more outputs for providing an output signal at a predetermined output frequency, wherein each input channel is coupled to a corresponding stage of the ring oscillator; and
a controller configured to generate one control signal per output, each control signal being configured to select an input channel among the plurality of input channels according to a predetermined sequence to obtain the output signal at the predetermined output frequency.

Optionally, the controller is coupled to the ring oscillator so as to receive at least one square wave signal from the ring oscillator, and wherein the at least one square wave signal is used as a clock signal to clock the controller.

Optionally, the controller is configured to select an input channel among the plurality of input channels at every rising edge and falling edge of the clock signal.

Optionally, the ring oscillator operates at a reference frequency so that each square wave signal has the same reference frequency, and wherein the predetermined output frequency of the output signal is a fraction of the reference frequency.

Optionally, wherein the fraction is a non-integral number.

Optionally, the controller comprises at least one finite state machine.

Optionally, wherein the at least one finite state machine is configured to receive a clock signal from the ring oscillator.

Optionally, the multiplexer has two outputs for providing a first output signal and a second output signal, and wherein the controller is configured to generate a first control signal having a first predetermined sequence, and a second control signal having a second predetermined sequence.

Optionally, wherein the two outputs are offset by a predetermined phase difference.

Optionally, wherein the first predetermined sequence and the second predetermined sequence are offset by a predetermined offset value to obtain the predetermined phase difference between the two outputs.

Optionally, the controller comprises a single finite state machine for generating the first and second control signals.

Optionally, the controller comprises a first finite state machine for generating the first control signal and a second finite state machine for generating the second control signal.

Optionally, wherein the ring oscillator comprises a first sub ring oscillator coupled to a second sub ring oscillator, wherein each sub ring oscillator has a same number of stages.

Optionally, wherein the first sub ring oscillator is coupled to the second sub ring oscillator via a plurality of latches.

Optionally, wherein the square wave signals provided by the ring oscillator have different phases.

According to a second aspect of the disclosure, there is provided a method of generating a signal having a predetermined output frequency, the method comprising:
providing a ring oscillator comprising a plurality of stages, and for each stage generating a corresponding square wave signal;
providing a multiplexer having a plurality of input channels and one or more outputs for providing the output signal at the predetermined output frequency, wherein each input channel is coupled to a corresponding stage of the ring oscillator; and
generating with a controller one control signal per output of the multiplexer, wherein each control signal selects an input channel among the plurality of input channels according to a predetermined sequence to obtain the output signal at the predetermined output frequency.

### DESCRIPTION OF THE DRAWINGS

The disclosure is described in further detail below by way of example and with reference to the accompanying drawings, in which:

FIG. 1 is a diagram of a frequency synthesizer according to the disclosure;

FIG. 2 is a diagram of a specific implementation of the frequency synthesizer of FIG. 1;

FIG. 3 is a plot illustrating the operation of the frequency synthesizer of FIG. 2;

FIG. 4 is a flow chart of a method for generating a signal having a predetermined output frequency according to the disclosure.

### DESCRIPTION

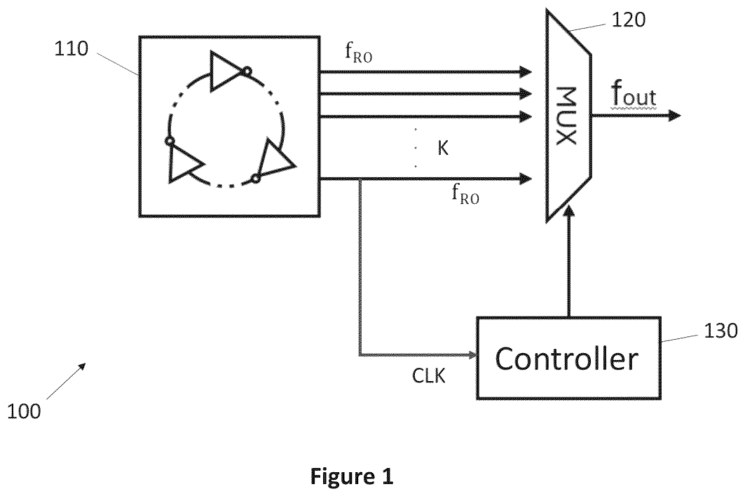

FIG. 1 is a diagram of a frequency synthesizer according to the disclosure. The frequency synthesizer 100 includes a ring oscillator 110 coupled to a multiplexer 120 and a controller 130. The ring oscillator 110 has a plurality K of stages so that each stage provides a corresponding square wave signal. Two consecutive stages are separated by a node for providing the corresponding square wave signal. The multiplexer 120 has a plurality M of input channels and one or more outputs, so that in use each output provides an output signal at a predetermined output frequency. Each input channel is coupled to a corresponding stage of the ring oscillator 110. The controller 130 may comprise one or more state machines, such as a finite state machines FSMs. The controller 130 may also be coupled to the ring oscillator 110 so as to receive a square wave signal from one of the stages, and used as a clock signal CLK. Should the controller 130 require additional clock signals, additional connections can be implemented between the controller 130 and the ring oscillator at different nodes/stages.

In operation, the controller 130 generates one control signal per output. Each control signal is configured to select an input channel among the plurality of input channels according to a predetermined sequence to obtain the output signal at a predetermined output frequency f_{OUT}. The predetermine sequence may include a pattern or cycle that repeated iteratively.

The ring oscillator 110 operates at a reference frequency f_{RO} so that each square wave signal has the same reference frequency f_{RO} and different phases. The predetermined output frequency of the output signal is a fraction R_mux of the reference frequency so that f_{OUT}=R_mux f_{RO} in which the fraction R_mux is a non-integral number.

The frequency synthesizer 100 enables the synthesis of various frequency ratio factors, denoted R_mux, determined by the relation R_mux=K/(K+2x), in which x∈N is a tunable parameter that defines the average pattern of ring oscillator node selection, and K is the number of stages of the ring oscillator as defined above.

The controller 130 (for instance, an FSM) selects an input channel among the plurality of input channels of the multiplexer 120 at every rising edge and falling edge of the clock signal. The controller 130 controls a repetitive pattern that may include holding on in one node or jumping by x nodes to achieve the correct output frequency and phase. Thus, x reflects the average node spacing strategy rather than a fixed skip per cycle. As a result, the multiplexer 120 does not necessarily advance by exactly x stages on every clock cycle. For example, if x=1, in every clock edge the sequence may be advancing to the next node or stay in the same node. In general, the next node has a phase difference of 360/k with the current node.

The example shown in FIG. 1 produces a single output with a non-integer multiplied frequency, however it will be appreciated that the frequency synthesizer 100 can be modified to produce two or more outputs. In this case, the controller 130 would be configured to provide corresponding control signals. These outputs may have a standard offset difference, governed by the offset of the corresponding control signals.

Compared with traditional non-integer frequency synthesizers, the frequency synthesizer 100 has a relatively low power consumption and improved settling time. It can also be implemented with a compact design, hence reducing the circuit footprint.

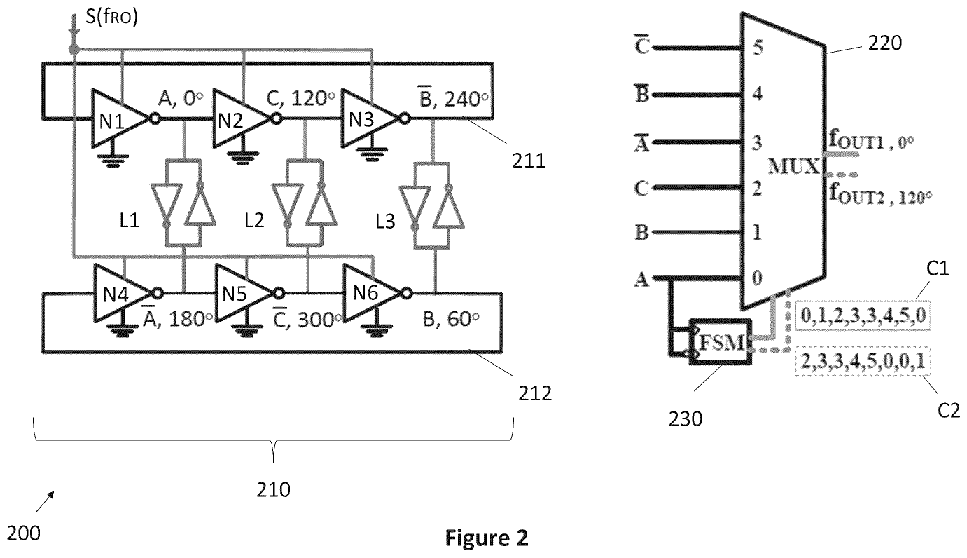

FIG. 2 is a diagram of a specific implementation of the frequency synthesizer of FIG. 1. The frequency synthesizer 200 includes a ring oscillator 210 coupled to a multiplexer 220 and a finite state machine FSM 230.

The ring oscillator 210 is a 6-stage ring oscillator that includes a first sub ring oscillator 211 coupled to a second sub ring oscillator 212, each having a same number of stages, in this example three stages. The first sub ring oscillator 211 is coupled to the second sub ring oscillator 212 via a plurality of latches labelled L1, L2, L3.

The first sub ring oscillator 211 is formed of three inverters (logical NOT gates) labelled N1, N2, N3 arranged in a ring, such that the output of the inverter at the end of the chain is fed back into the first inverter. The second sub ring oscillator 212 is also formed of three inverters arranged in a ring and labelled N4, N5, N6. Each inverter is adapted to receive a setting signal S(f_{RO}) for setting the reference frequency f_{RO} of the ring oscillator. For instance, the setting signal may be a current or a voltage. All inverters receive the same setting signal S(f_{RO}).

Two consecutive stages are separated by a node for providing a corresponding square wave signal. The node after inverter N1, referred to as node 1, is coupled to the node after N4 (node 4) via the latch L1. Similarly, the node after inverter N2 (node 2) is coupled to the node after N5 (node 5) via the latch L2. The node after inverter N3 (node 3) is coupled to the node after N6 (node 6) via the latch L3.

The latches L1, L2 and L3 ensure proper phase difference between the pairs of AĀ, BB̅, CC̅. In this case the latches ensure a phase difference of 180° (opposite phase). The node 1 carries the square wave signal A,0° and the node 4 carries the square wave signal Ā,180°. The node 2 carries the square wave signal C,120° and the node 5 carries the square wave signal C̅,300°. The node 3 carries the square wave signal B̅,240° and the node 6 carries the square wave signal B,60°.

The multiplexer 220 has six inputs labelled 0 to 5 and two outputs OUT1 and OUT2. The inputs of the multiplexer 220 are connected to specific nodes of the ring oscillator. The input labeled 0 is connected to the node 1 after N1. The input labeled 1 is connected to the node 6 after N6. The input labeled 2 is connected to the node 2 after N2. The input labeled 3 is connected to the node 4 after N4. The input labeled 4 is connected to the node 3 after N3. The input labeled 5 is connected to the node 5 after N5.

The FSM 230 is configured to generate a first control signal C1 having a first predetermined sequence, and a second control signal C2 having a second predetermined sequence. Both control signals C1 and C2 follow a repeating pattern. In this example the first sequence is given by the sequence of inputs “0,1,2,3, 3,4,5,0” (to be repeated) and the second sequence is given by the sequence of inputs “2,3,3,4,5,0,0,1” (to be repeated).

The two patterns are offset in a manner that ensures the nodes of the ring oscillator 210 are sampled with a corresponding offset that results in the phase difference of 120° between the two outputs of the multiplexer 220.

In the present example x=1, and therefore in every clock edge the sequence advances by one node, or remains on the same node.

In general, the next node has phase difference of 360/k with the current node. For example, for fout1, as shown in FIG. 2, the sequence of the first control signal C1 starts with channel 0 (connected to node 1 after N1 to receive A with phase 0) , then advances by 1 (x=1) to channel 1 connected to node 6 after N6 to receive B with phase 60 (360/6=60)), then advances by 1 to channel 2 (connected to node 2 after N2 to receive C with phase 120), then the sequence advances by 1 to channel 3 (connected to node 4 after N4 to receive Ā with phase 180) and stay at channel 3 for two clock cycles, then the sequence advances by 1 to channel 4 (connected to node 3 after N3 to receive B̅with phase 240), then the sequence advances by 1 to channel 5 (connected to node 5 after N5 to receive C̅ with phase 300), then the sequence advances by 1 to channel 0 (connected to node 1 after N1 to receive A with phase 360=0). This cycle or pattern is then repeated iteratively.

The FSM 230 is clocked by one of the square wave signals from the ring oscillator 210. In this example the FSM is clocked by A, Ā, hence making the multiplexer as a self-clock multiplexer. This provides several advantages.

Firstly, by deriving the multiplexer clock signal directly from a ring oscillator node, the multiplexer's state transitions are inherently synchronized with the ring oscillator's oscillation. This eliminates the need for any external synchronization or timing alignment between an independent clock domain and the ring oscillator.

Secondly, since every ring oscillator node has a fixed, deterministic phase relationship relative to the node used as the clock, the multiplexer knows exactly which ring oscillator nodes are high or low at each transition. This allows precise control of which node to select next (the “jump”) to achieve the desired fractional factor (e.g., Rmux=K/(K+2x).

Thirdly, if the multiplexer was clocked by an external or an asynchronous clock, one would risk metastability and phase uncertainty when sampling the ring oscillator node states. Using a ring oscillator node as CLK ensures that all transitions occur within the same timing domain.

Fourthly, this approach avoids additional synchronization logic, reduces power, and maintains deterministic output frequency ratios, which is critical for predictable injection-locking performance.

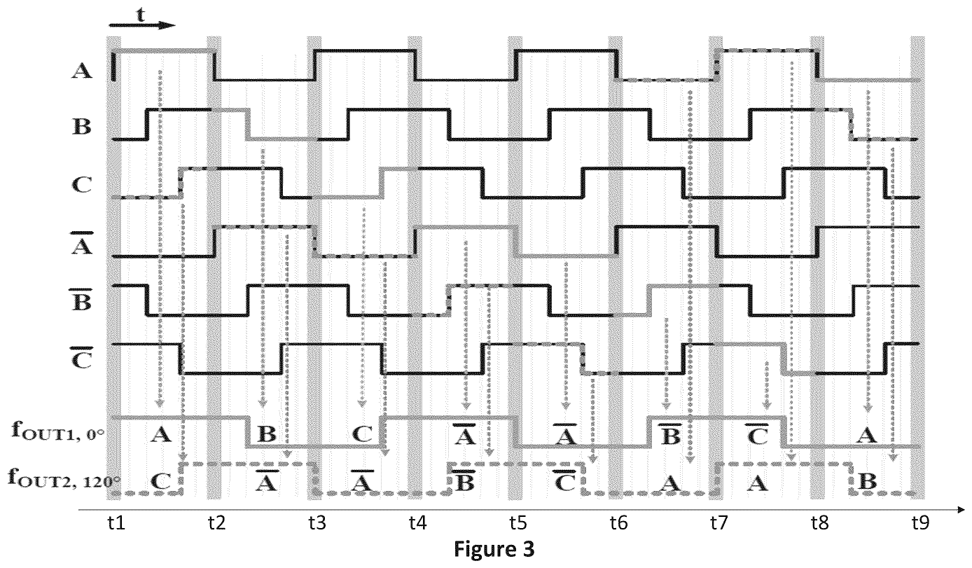

FIG. 3 is a plot illustrating the operation of the frequency synthesizer of FIG. 2. FIG. 3 shows the square wave waveforms A, B, C, Ā, B̅, C̅ obtained at the six nodes of the ring oscillator and two outputs OUT1 and OUT2 of the multiplexer.

As explained above, the square wave signal A from the first node is used to clock the FSM 230. The rising and falling edges of the clock signal A are highlighted by successive vertical lines at times t1 to t9.

The first output is obtained by following the first sequence “0,1,2,3,3,4,5,0” which corresponds to A between t1 and t2, B between t2 and t3, C between t3 and t4, A between t4 and t6, B between t6 and t7, C between t7 and t8, and A between t8 and t9. The second output is obtained by following the second sequence “2,3,3,4,5,0,0,1” using the same principle as shown in FIG. 3. As can be observed from FIG. 3, |F_out1,2|=6/(6+2) f_{RO}=¾ f_{RO}.

In the above-shown example, the two outputs of the multiplexer have the same frequency and a fixed phase difference. In other implementations, multiple FSMs may be provided to generate the control signals for the multiplexer. In this case the outputs of the multiplexer can have different frequencies that are different fractions of the ring oscillator frequency f_{RO}.

It will be appreciated that the ring oscillator 210 may be implemented using different topologies and is not restricted to the specific topology of FIG. 2.

Any topology capable of producing the signals AĀ, BB̅, CC̅ would be suitable. Similarly, the ring oscillator could be implemented with different numbers of stages. Depending on the application, more or less stages may be used.

It will also be appreciated that the number M of inputs of the multiplexer do not have to be equal to the number of stages of the ring oscillator. For example, if a 12-stage ring oscillator is available, one can choose to use only 6 of those stages and still generate the same output behavior shown in FIG. 3. The relation R_mux=K/(K+2x) described above still applies. To achieve R_mux=¾, several valid (K, x) solutions exist. For K=6 and x=1→one can advance by 1 node per clock cycle and use all 6 nodes. For K=12 and x=2→one can skip one node and select the next, using only 6 out of the 12 nodes. Therefore, depending on the desire frequency ratio one may decide to use all the nodes/stages of the ring oscillator or only a subset of stages/nodes.

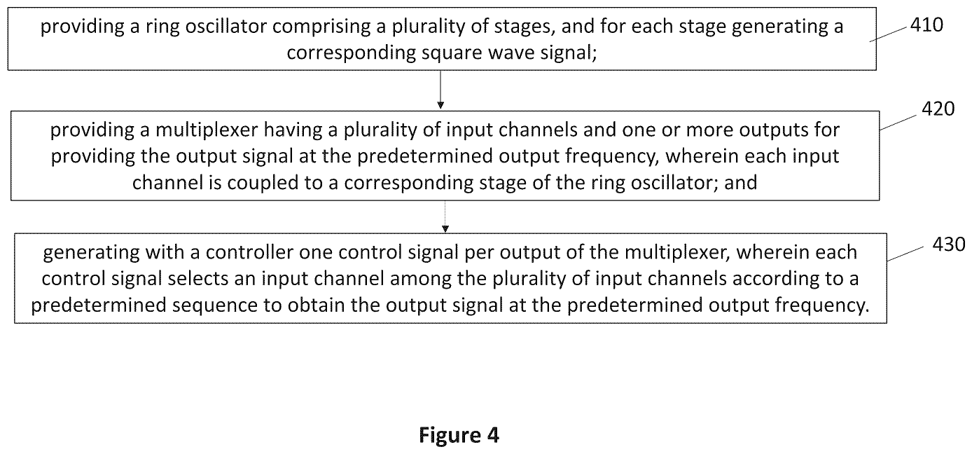

FIG. 4 is a flow chart of a method for generating a signal having a predetermined output frequency according to the disclosure.

At step 410, a ring oscillator comprising a plurality of stages is provided and for each stage a corresponding square wave signal is generated.

At step 420, a multiplexer is provided. The multiplexer has a plurality of input channels and one or more outputs for providing the output signal at the predetermined output frequency. Each input channel is coupled to a corresponding stage of the ring oscillator.

At step 430 one control signal per output of the multiplexer is generated using a controller. Each control signal selects an input channel among the plurality of input channels according to a predetermined sequence to obtain the output signal at the predetermined output frequency.

A skilled person will appreciate that variations of the disclosed arrangements are possible without departing from the disclosure. Accordingly, the above description of the specific embodiments is made by way of example only and not for the purposes of limitation. It will be clear to the skilled person that minor modifications may be made without significant changes to the operation described.

1. A frequency synthesizer comprising:
a ring oscillator comprising a plurality of stages, wherein each stage is configured to provide a corresponding square wave signal;
a multiplexer having a plurality of input channels and one or more outputs for providing an output signal at a predetermined output frequency, wherein each input channel is coupled to a corresponding stage of the ring oscillator; and
a controller configured to generate one control signal per output, each control signal being configured to select an input channel among the plurality of input channels according to a predetermined sequence to obtain the output signal at the predetermined output frequency.

2. The frequency synthesizer as claimed in claim 1, wherein the controller is coupled to the ring oscillator so as to receive at least one square wave signal from the ring oscillator, and wherein the at least one square wave signal is used as a clock signal to clock the controller.

3. The frequency synthesizer as claimed in claim 2, wherein the controller is configured to select an input channel among the plurality of input channels at every rising edge and falling edge of the clock signal.

4. The frequency synthesizer as claimed in claim 1, wherein the ring oscillator operates at a reference frequency so that each square wave signal has the same reference frequency, and wherein the predetermined output frequency of the output signal is a fraction of the reference frequency.

5. The frequency synthesizer as claimed in claim 4, wherein the fraction is a non-integral number.

6. The frequency synthesizer as claimed in claim 1, wherein the controller comprises at least one finite state machine.

7. The frequency synthesizer as claimed in claim 6, wherein the at least one finite state machine is configured to receive a clock signal from the ring oscillator.

8. The frequency synthesizer as claimed in claim 1, wherein the multiplexer has two outputs for providing a first output signal and a second output signal, and wherein the controller is configured to generate a first control signal having a first predetermined sequence, and a second control signal having a second predetermined sequence.

9. The frequency synthesizer as claimed in claim 8, wherein the two outputs are offset by a predetermined phase difference.

10. The frequency synthesizer as claimed in claim 9, wherein the first predetermined sequence and the second predetermined sequence are offset by a predetermined offset value to obtain the predetermined phase difference between the two outputs.

11. The frequency synthesizer as claimed in claim 8, wherein the controller comprises a single finite state machine for generating the first and second control signals.

12. The frequency synthesizer as claimed in claim 8, wherein the controller comprises a first finite state machine for generating the first control signal and a second finite state machine for generating the second control signal.

13. The frequency synthesizer as claimed in claim 1, wherein the ring oscillator comprises a first sub ring oscillator coupled to a second sub ring oscillator, wherein each sub ring oscillator has a same number of stages.

14. The frequency synthesizer as claimed in claim 13, wherein the first sub ring oscillator is coupled to the second sub ring oscillator via a plurality of latches.

15. The frequency synthesizer as claimed in claim 1, wherein the square wave signals provided by the ring oscillator have different phases.

16. A method of generating a signal having a predetermined output frequency, the method comprising:
providing a ring oscillator comprising a plurality of stages, and for each stage generating a corresponding square wave signal;
providing a multiplexer having a plurality of input channels and one or more outputs for providing the output signal at the predetermined output frequency, wherein each input channel is coupled to a corresponding stage of the ring oscillator; and
generating with a controller one control signal per output of the multiplexer, wherein each control signal selects an input channel among the plurality of input channels according to a predetermined sequence to obtain the output signal at the predetermined output frequency.
